(19) United States
(12) Patent Application Publication
(10) Pub. No.: US 2023/0197900 A1
(43) Pub. Date: Jun. 22, 2023

(54) DISPLAY PANEL, MANUFACTURING METHOD THEREOF, AND MOBILE TERMINAL

(71) Applicants: HUIZHOU CHINA STAR OPTOELECTRONICS DISPLAY CO., LTD., Huizhou, Guangdong (CN); Shenzen China Star Optoelectronics Semiconductor Display Technology Co., LTD., Shenzhen, Guangdong (CN)

(72) Inventors: Zhiqing SHI, Huizhou, Guangdong (CN); Jinyang ZHAO, Huizhou, Guangdong (CN); Lixuan CHEN, Huizhou, Guangdong (CN)

(21) Appl. No.: 17/623,917

(22) PCT Filed: Dec. 22, 2021
(86) PCT No.: PCT/CN2021/140279

§ 371 Date: Dec. 30, 2021

(30) Foreign Application Priority Data
Dec. 16, 2021 (CN) 202111546370.1

(51) Int. Cl. H01L 33/38; H01L 33/62; H01L 33/00; H01L 25/075

(52) U.S. Cl. CPC H01L 33/382; H01L 33/62; H01L 33/005; H01L 25/0753; H01L 2933/0016; H01L 2933/0066

(57) ABSTRACT

The present disclosure provides a display panel, a manufacturing method thereof, and a mobile terminal. The display panel includes a plurality of pixel units, each pixel unit includes: a plurality of light-emitting units, wherein adjacent two of the light-emitting units are separately arranged; and an electrode assembly including at least two opposite and insulated power electrodes, wherein each light-emitting unit is electrically connected to adjacent two of the power electrodes.

### FIELD OF INVENTION

The present disclosure relates to the technical field of display, and specifically to a display panel, a manufacturing method thereof, and a mobile terminal.

### BACKGROUND OF INVENTION

A light-emitting diode (LED) is a fully solid-state-semiconductor light-emitting component with characteristics of small size, high luminous efficiency, low cost, and long life. Over the years, with the rapid development of LED display technology, applications of LEDs to large-size displays have become present technical hotspots.

However, in the field of large-size LED displays, a massive amount of LED chips needs to be transferred. Simultaneously, the yield of the LED chips need to be strictly controlled, thereby consuming a lot of time and increasing production costs.

### SUMMARY OF INVENTION

There are technical problems in a large-size LED display field to consume a lot of time and increase production costs for transferring a massive amount of LED chips.

The present disclosure provides a display panel, a manufacturing method thereof, and a mobile terminal to overcome the technical problems of increased time and production cost caused by transferring a massive amount of LED chips in the current LED large-size display field.

To solve the above technical problems, technical solutions provided by the present disclosure are described as follows.

The present disclosure provides a display panel. The display panel includes a plurality of pixel units, wherein each of the pixel units includes:

A plurality of light-emitting units, wherein adjacent two of the light-emitting units are separately arranged; and

An electrode assembly including at least two opposite and insulated power electrodes, wherein each of the light-emitting units is electrically connected to adjacent two of the power electrodes.

In the display panel of the present disclosure, the electrode assembly includes:

A first power electrode including a plurality of first branch electrodes, wherein adjacent two of the first branch electrodes are arranged in parallel.

In the display panel of the present disclosure, the electrode assembly further includes a second power electrode, the second power electrode includes a plurality of second branch electrodes, and adjacent two of the second branch electrodes are arranged in parallel.

In the display panel of the present disclosure, the first branch electrodes and the second branch electrodes are arranged in parallel and alternatively.

In the display panel of the present disclosure, each of the light-emitting units is electrically connected to two adjacent first and second branch electrodes.

In the display panel of the present disclosure, the first power electrode further includes a first side-branch electrode electrically connected to the first branch electrodes.

In the display panel of the present disclosure, the second power electrode further comprises a second side-branch electrode electrically connected to the second branch electrodes.

In the display panel of the present disclosure, the first side-branch electrode and the second side-branch electrode are arranged in parallel.

In the display panel of the present disclosure, a direction that the first side-branch electrode and the second side-branch electrode extend is perpendicular to a direction that the first branch electrodes and the second branch electrodes are arranged.

In the display panel of the present disclosure, the first branch electrodes and the second branch electrodes are located between the first side-branch electrode and the second side-branch electrode.

In the display panel of the present disclosure, each of the first branch electrodes and the second branch electrodes is a linear electrode formed in a straight-line shape, a broken-line shape, or a curved shape.

In the display panel of the present disclosure, in a direction that the first branch electrodes and the second branch electrodes are arranged, a length of each of the light-emitting units is greater than or equal to a distance between the first and second branch electrodes.

In the display panel of the present disclosure, in the direction that the first branch electrodes and the second branch electrodes are arranged, the length of each of the light-emitting units is smaller than twice the distance between the first and second branch electrodes.

In the display panel of the present disclosure, the display panel further includes a quantum-dot glue layer disposed on the electrode assembly.

In the display panel of the present disclosure, the quantum-dot glue layer covers the light-emitting units.

In the display panel of the present disclosure, the display panel further includes an encapsulation glue layer disposed between the electrode assembly and the quantum-dot glue layer.

In the display panel of the present disclosure, the encapsulation glue layer covers the light-emitting units.

In the display panel of the present disclosure, a material of each of the light-emitting units includes a semiconductor compound composed of at least two elements of boron group elements, carbon group elements, and nitrogen group elements.

The present disclosure also provides a method for manufacturing a display panel, including:

Manufacturing a plurality of electrode assemblies on a substrate to make each of the electrode assemblies comprise at least two opposite and insulated power electrodes; and

Manufacturing light-emitting units on each of the electrode assemblies to make the light-emitting units be electrically connected to adjacent two of the power electrodes.

The present disclosure also provides a mobile terminal, which includes a terminal body and the display panel mentioned above, wherein the terminal body and the display panel are combined into a whole.

In the present disclosure, the electrode assembly is disposed in each of the pixel units, and the light-emitting units are disposed between and electrically connected to at least two opposite and insulated power electrodes of the electrode assembly, so that the light-emitting units are arranged within the electrode assembly in an orderly manner, thereby achieving effects of more uniform light emission and stronger brightness. Moreover, by the above structure, the present disclosure can save a massive transfer process of chips, thereby overcoming disadvantages of strict and time-consuming chip yield control requirements caused by the massive transfer process of chips, which is beneficial to reduce the production cost of LED large-size display equipment.

### BRIEF DESCRIPTION OF DRAWINGS

In order to explain technical solutions in the embodiments of the present disclosure more clearly, drawings used to describe the embodiments will be briefly introduced as follows. Obviously, the drawings in the following description are only a part of embodiments of the present disclosure. Other drawings can be obtained based on these drawings without creative work for those skilled in the art.

FIG. 1 is a schematic diagram of a planar structure of a display panel of the present disclosure;

FIG. 2 is a schematic diagram of a planar structure of an electrode assembly of the present disclosure;

FIG. 3 is a schematic diagram of a connection structure between a light-emitting unit and power electrodes of the present disclosure;

FIG. 4 is a schematic diagram of a first structure of the electrode assembly of the present disclosure;

FIG. 5 is a schematic diagram of a second structure of the electrode assembly of the present disclosure;

FIG. 6 is a schematic structural diagram of a quantum-dot glue layer on the electrode assembly of the present disclosure;

FIG. 7 is a schematic diagram of a first positioned structure of the quantum-dot glue layer and the electrode assembly of the present disclosure;

FIG. 8 is a schematic diagram of a second positioned structure of the quantum-dot glue layer and the electrode assembly of the present disclosure;

FIG. 9 is a flowchart of a method for manufacturing a display panel of the present disclosure.

### DESCRIPTION OF REFERENCE SIGNS

Pixel unit: 100; light-emitting unit: 200; electrode assembly: 300; first power electrode 310; first branch electrode: 311; first side-branch electrode: 312; first trunk electrode: 313; second power electrode: 320; second branch electrode: 321; second side-branch electrode: 322; second trunk electrode: 323: quantum-dot glue layer: 400; encapsulation glue layer: 500; array substrate: 600; array driving layer: 610; data line: 611; scan line: 612.

### DETAILED DESCRIPTION OF PREFERRED EMBODIMENTS

Technical solutions in embodiments of the present disclosure will be clearly and completely described below in conjunction with the drawings in the embodiments of the present disclosure. Obviously, the described embodiments are only a part of embodiments of the present disclosure rather than all of the embodiments. Based on the embodiments in the present disclosure, all other embodiments obtained by those skilled in the art without creative work shall fall within the protection scope of the present disclosure. In addition, it should be understood that specific implementations described herein are only used to illustrate and explain the present disclosure and are not used to limit the present disclosure. In this application, in the absence of explanation to the contrary, orientation words used herein such as “upper” and “lower” generally refer to upper and lower directions of a device in actual use or working state, and specifically refer to drawing directions in the drawings; and “inner” and “outer” refer to an outline of the device.

A light-emitting diode (LED) is a fully solid-state-semiconductor light-emitting device with characteristics of small size, high luminous efficiency, low cost, and long life. In addition, LEDs also have many advantages such as high color gamut, high brightness, long life, and real-time color control. Over the years, with the rapid development of LED display technology, applications of LEDs to large-size displays have become present technology hotspots. However, in the field of large-size LED displays, a massive amount of LED chips needs to be transferred. Simultaneously, the yield of the LED chips needs to be strictly controlled, thereby consuming a lot of time and increasing production costs. The present disclosure proposes the following solutions based on the above technical problems.

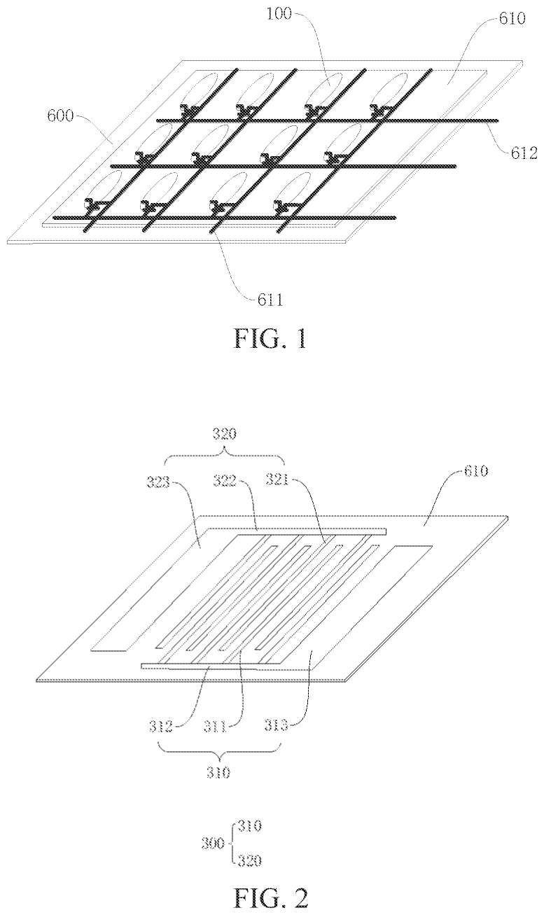

Referring to FIGS. 1 to 7, the present disclosure provides a display panel. The display panel includes a plurality of pixel units 100. Each of the pixel units 100 includes:

a plurality of light-emitting units 200, wherein adjacent two of the light-emitting units 200 are separately arranged; and

an electrode assembly 300 includes at least two opposite and insulated power electrodes, and each of the light-emitting units 200 is electrically connected to two adjacent power electrodes.

In the present disclosure, the electrode assembly 300 is disposed within each of the pixel units 100, and the light-emitting units 200 electrically connected to the power electrodes are disposed between at least two opposite and insulated power electrodes of the electrode assembly 300, so that the light-emitting units 200 are arranged within the electrode assembly 300 in an orderly manner, thereby achieving effects of more uniform light emission and stronger brightness. Moreover, by the above structure, the present disclosure can save a massive transfer process of chips, thereby overcoming disadvantages of strict and time-consuming chip yield control requirements caused by the massive transfer process of chips, which is beneficial to reduce the production cost of LED large-size display equipment.

Now, the technical solutions of the present disclosure will be described in conjunction with specific embodiments. Detailed descriptions are given below. It should be noted that the order of description in the following embodiments is not meant to limit the preferred order of the embodiments.

In the display panel of the present disclosure, the display panel may further include an array substrate 600, on which an array driving layer 610 is provided. The array driving layer 610 includes a plurality of data lines 611 and a plurality of scan lines 612. The data lines 611 and the scan lines 612 are staggered horizontally and vertically to form a grid structure. The pixel unit 100 is arranged within the grid structure.

In this embodiment, the light-emitting unit 200 may be made of nano-scale-semiconductor light-emitting materials. For example, the light-emitting unit 200 may be prepared from a semiconductor compound composed of at least two elements from group IIIA to group VA, such as InGaN, GaN, GaP, GaAs, GaAsP, and other semiconductor compounds.

In this embodiment, the light-emitting unit 200 is manufactured by using a semiconductor compound composed of at least two elements from group IIIA to group IVA, which can give the light-emitting unit 200 good luminous intensity and small-size performance, thereby giving a nano-scale light-emitting unit 200 (i.e., nanorod light-emitting diode (Nanorod LED) with more excellent luminous performance and stability. In addition, because the size of the light-emitting unit 200 reaches the nanometer level, in which a current is smaller, and a corresponding voltage drop (IR-Drop, referring to a phenomenon that points out a voltage dropping or rising on the power supply and ground network in an integrated circuit) will be smaller, and uniformity and color performance of the display panel will be better.

In this embodiment, the power electrodes within the electrode assembly 300 may be made of conductive materials, such as Ag, alloy with Ag and Al, Mo, alloy with Mo and Al, TiO, and other conductive materials. Alternatively, the power electrode can also be made of conductive paint or conductive film material by patterning treatment, such as ITO (Indium Tin Oxide) and the like.

Please refer to FIG. 2, which is a schematic structural diagram of the electrode assembly 300 according to the present disclosure. In the display panel of the present disclosure, the electrode assembly 300 includes:

A first power electrode 310, wherein the first power electrode 310 includes a plurality of first branch electrodes 311, and two adjacent first branch electrodes 311 are arranged in parallel;

A second power electrode 320, wherein the second power electrode 320 includes a plurality of second branch electrodes 321, and two adjacent second branch electrodes 321 are arranged in parallel;

The first branch electrodes 311 and the second branch electrodes 321 are arranged in parallel and alternatively, and each light-emitting unit 200 is electrically connected to two adjacent first and second branch electrodes 311 and 321.

In this embodiment, the first power electrode 310 is configured to include a plurality of first branch electrodes 311, and the second power electrode 320 is configured to include a plurality of second branch electrodes 321, so that it is possible to form more electrode assemblies 300 that can be electrically connected to the light-emitting unit 200 in one of the pixel units 100, thereby facilitating the reduction of the size of the light-emitting unit 200, so that more light-emitting units 200 can be arranged within the pixel unit 100 with limited space, thereby increasing the display brightness and improving uniformity of light emission.

Referring to FIG. 2, in the display panel of the present disclosure, the first power electrode 310 further includes a first side-branch electrode 312 electrically connected to the first branch electrodes 311, and the second power electrode 320 also includes a second side-branch electrode 322 electrically connected to the second branch electrodes 321.

In this embodiment, both of the first side-branch electrode 312 and the second side-branch electrode 322 may be a linear electrode, and the first side-branch electrode 312 may be connected to the same end of each of the first branch electrodes 311. Namely, the first branch electrodes 311 are located on the same side of the first side-branch electrode 312. The second side-branch electrode 322 may also be connected to the same end of each of the second branch electrodes 321. In other words, the second branch electrodes 321 are located on the same side of the second branch electrode 321.

In this embodiment, the first branch electrodes 311 are connected to the first side-branch electrode 312, and the second branch electrodes 321 are electrically connected to the second side-branch electrode 322, so that the first side-branch electrode 312 can connect the first branch electrodes 311 in series to be provided with electric power, and the second side-branch electrode 322 can connect the second branch electrodes 321 in series to be provided with electric power, thereby eliminating wiring provided for each branch electrode, which is beneficial to reduce the internal electrode wiring density within each of the light-emitting units 200, to reduce the manufacturing cost, and improve the circuit stability.

In this embodiment, the first side-branch electrode 312 and the second side-branch electrode 322 are arranged in parallel, and a direction that the first side-branch electrode 312 and the second side-branch electrode 322 extend is perpendicular to a direction that the first branch electrodes 311 and the second branch electrodes 321 are arranged, so that wiring of the first side-branch electrode 312 and the second side-branch electrode 322 is arranged easier, thereby reducing the difficulty of the manufacturing process while simplifying the structure of the trunk electrode to reduce circuit failures.

In this embodiment, the first power electrode 310 may further include a first trunk electrode 313, and the second power electrode 320 may further include a second trunk electrode 323. The first trunk electrode 313 is connected to the first side-branch electrode 312, and the second trunk electrode 323 is connected to the second side-branch electrode 322. In this embodiment, the first trunk electrode 313 and the second trunk electrode 323 may be arranged in parallel with the first branch electrodes 311 and the second branch electrodes 321. The first trunk electrode 313 and the second trunk electrode 323 are respectively disposed at two ends in the arrangement direction of the first branch electrodes 311 and the second branch electrodes 321.

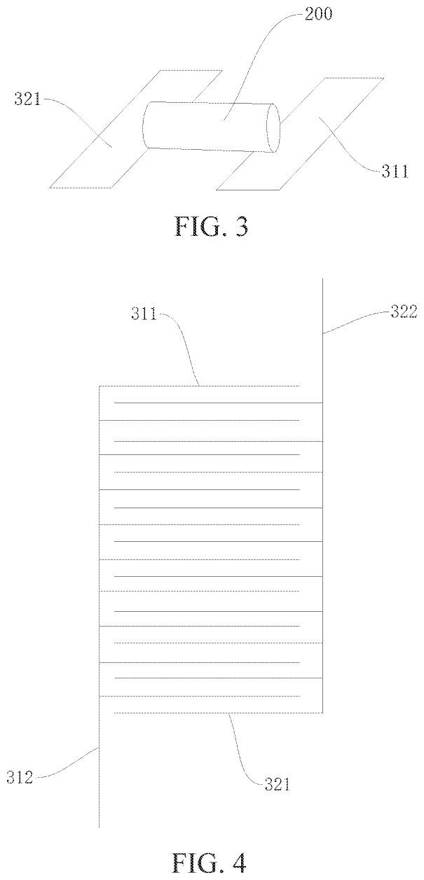

Please refer to FIGS. 2 and 3, FIG. 3 is a schematic diagram of a connection structure between the light-emitting unit 200 and the power electrodes of the present disclosure. In the display panel of the present disclosure, the first branch electrodes 311 and the second branch electrodes 321 are located between the first side-branch electrode 312 and the second side-branch electrode 322, so that the first side-branch electrode 312, the second side-branch electrode 322, the first branch electrodes 311, and the second branch electrodes 321 form an electrode area with a regular shape, to facilitate the subsequent arrangement of the light-emitting units 200 in the electrode area. The light-emitting units 200 do not easily go beyond the electrode area under the action of electric field force, to reduce the waste of the light-emitting unit 200.

In this embodiment, the first branch electrodes 311 and the second branch electrodes 321 may be linear electrodes formed in a straight-line shape, a broken-line shape, or a curved shape. In this embodiment, by configuring the first branch electrodes 311 and the second branch electrodes 321 as linear electrodes, it is convenient to separate two adjacent first branch electrode 311 and second branch electrode 321 so that a distance between them is matched with the size of the nano-scale light-emitting units 200, to improve power supply stability of the light-emitting units 200. Moreover, the linear branch electrodes can be densely arranged to form gaps in the order of nano scale, thereby helping to reduce the area of each light-emitting unit 200 and improve the display resolution.

In this embodiment, first ends of the first branch electrodes 311 are connected to the first side-branch electrode 312, and second ends of the first branch electrodes 311 extend toward the second side-branch electrode 322, but there are gaps between the second ends of the first branch electrodes 311 and the second side-branch electrode 322 to realize an insulation configuration between the first branch electrodes 311 and the second side-branch electrode 322. Correspondingly, first ends of the second branch electrodes 321 are connected to the second side-branch electrode 322, and second ends of the second branch electrodes 321 extend toward the first side-branch electrode 312, but there are gaps between the second ends of the second branch electrodes 321 and the first side-branch electrode 312 to achieve an insulation configuration between the second branch electrodes 321 and the first side-branch electrode 312.

Please refer to FIG. 4, which is a schematic diagram of a first structure of the electrode assembly 300 according to the present disclosure. In this embodiment, when the first branch electrodes 311 and the second branch electrodes 321 are in a linear form, the first branch electrodes 311 may be arranged perpendicular to the first side-branch electrode 312, and the second branch electrodes 321 may be arranged perpendicular to the second side-branch electrode 322. At present, the length of each of the first branch electrodes 311 and the second branch electrodes 321 is smaller than a distance between the first side-branch electrode 312 and the second side-branch electrode 322.

Alternatively, each of the first branch electrodes 311 may form an angle in a non-zero and non-right angle manner with the first side-branch electrode 312, and each of the second branch electrodes 321 may form an angle in a non-zero and non-right angle manner with the second side-branch electrode 322. At present, the length of each of the first branch electrodes 311 and the second branch electrodes 321 may be greater than or equal to a distance between the first side-branch electrode 312 and the second side-branch electrode 322. In this embodiment, the above configurations can be used to make wiring of the first branch electrodes 311 and the second branch electrodes 321 more direct and convenient, to reduce the difficulty of the wiring process of the branch electrodes.

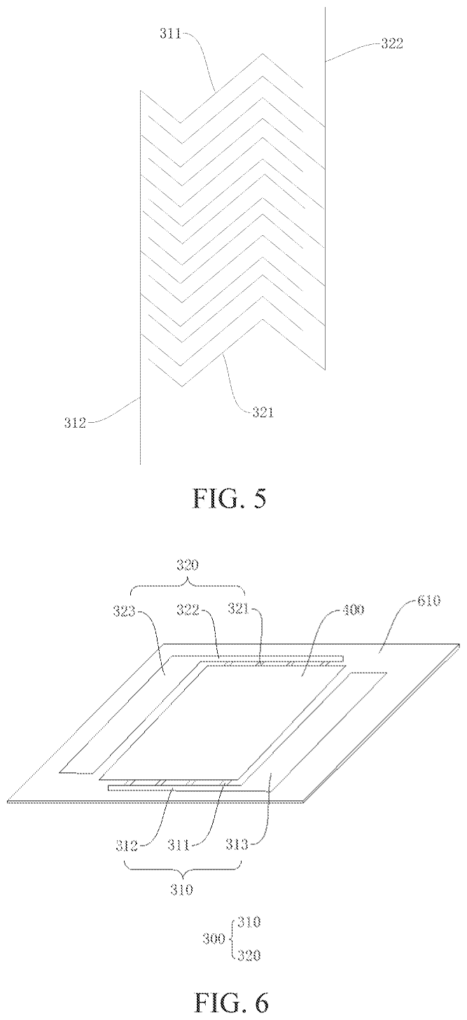

Please refer to FIG. 5, which is a schematic diagram of a second structure of the electrode assembly 300 according to the present disclosure. In this embodiment, when the first branch electrodes 311 and the second branch electrodes 321 are in a broken-line shape or a curved shape, an angle between each first branch electrode 311 and the first side-branch electrode 312 can be any non-zero angle, and the length of each of the first branch electrodes 311 can be greater than a distance between the first side-branch electrode 312 and the second side-branch electrode 322. Correspondingly, an angle between each second branch electrode 321 and the second side-branch electrode 322 can be any non-zero angle, and the length of each of the second branch electrodes 321 can be greater than a distance between the first side-branch electrode 312 and the second side-branch electrode 322. In this embodiment, by the above configuration, the length of each of the first branch electrodes 311 and the second branch electrodes 321 between the first side-branch electrode 312 and the second side-branch electrode 322 can be longer, so that more light-emitting units 200 can be arranged, which is beneficial to further increase the brightness and uniformity of light emitting, and to improve the display effect.

Please refer to FIG. 3, in the display panel of the present disclosure, in a direction that the first branch electrodes 311 and the second branch electrodes 321 are arranged, a length of each of the light-emitting units 200 is greater than or equal to a distance between the first branch electrode 321 such that the light-emitting units 200 can be overlapped between the first branch electrodes 311 and the second branch electrodes 321 with different electric potentials, to implement a function for energized to emit light of the light-emitting units 200.

In this embodiment, in a direction that the first branch electrodes 311 and the second branch electrodes 321 are arranged, a length of each of the light-emitting units 200 may be smaller than twice the distance between the first branch electrode 311 and the second branch electrode 321. In other words, each of the light-emitting units 200 overlaps at most one first branch electrode 311 and one second branch electrode 321. The first branch electrode 311 and the second branch electrode 321 overlapped by the light-emitting unit 200 are arranged adjacent to each other to avoid the light-emitting units 200 overlapping several first branch electrodes 311 or several second branch electrodes 321 at the same time, causing a problem of unstable light-emitting performance of the light-emitting units 200.

Please refer to FIG. 6, which is a schematic structural diagram of a quantum-dot glue layer 400 on the electrode assembly 300 of the present disclosure. In the display panel of the present disclosure, the display panel further includes a quantum-dot glue layer 400 disposed on the electrode assembly 300, wherein the quantum-dot glue layer 400 covers the light-emitting units 200.

In this embodiment, the quantum-dot glue layer 400 may be composed of WA group elements, IIB-VIA group elements, IVA-VIA group elements, or IIIB-VA group elements, mainly IIIA-VA group elements (such as InP, GaAs, and the like) or IIB-group elements (such as CdSe, ZnS, CdS, and the like). In addition, the quantum-dot glue layer 400 may also be made of materials including other high-stability composite quantum-dot materials (such as hydrogel-loaded QD structure, CdSe—SiO₂, and the like) and perovskite quantum dots.

In this embodiment, a quantum-dot glue layer 400 is provided on the light-emitting units 200 to combine quantum dot and LED technologies and utilize the photoluminescence properties of quantum dots (which can emit different colors of fluorescence under the excitation of light) and the excellent color performance of quantum dots (the color gamut of quantum dot materials can reach 110% of the NTSC standard color gamut), which gives the display panel more excellent color performance, and can significantly improve light efficiency of the entire display panel and reduce the IR drop, to be more energy-saving, which is conducive to the manufacture of large-size-quantum-dot LED display components (QD-LED components) or display devices.

In this embodiment, because the quantum-dot glue layer 400 is disposed on the electrode assembly 300, the electrode assembly 300 can supply power to the light-emitting units 200 and provide power to the quantum-dot glue layer 400. So, the light-emitting units 200 and their corresponding quantum-dot glue layer 400 achieve effects of synchronous light emission and color enhancement.

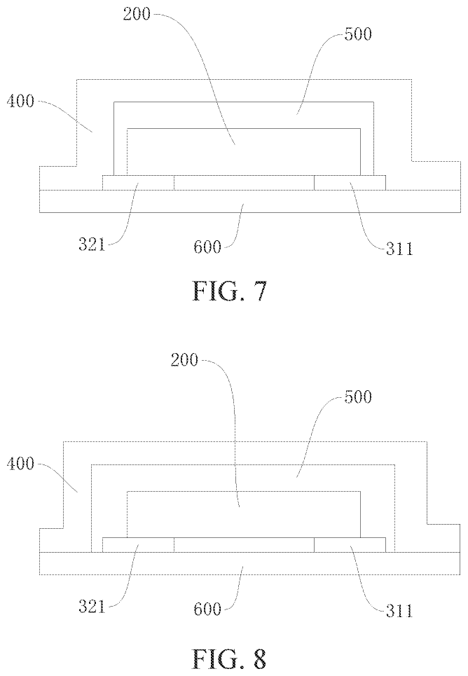

Please refer to FIGS. 7 and 8, FIG. 7 is a schematic diagram of a first positioned structure of the quantum-dot glue layer 400 and the electrode assembly 300 according to the present disclosure, and FIG. 8 is a schematic diagram of a second positioned structure of the quantum-dot glue layer 400 and the electrode assembly 300 according to the present disclosure. In the display panel of the present disclosure, the display panel further includes an encapsulation glue layer 500 disposed between the electrode assembly 300 and the quantum-dot glue layer 400. The encapsulation glue layer 500 covers the light-emitting units 200. In this embodiment, by disposing the encapsulation glue layer 500 on the electrode assembly, positions of the light-emitting units 200 overlapping the first branch electrodes 311 and the second branch electrodes 321 within the electrode assembly 300 can be fixed and strengthened. The electrical connection stability between the light-emitting units 200 and the electrode assembly 300 is improved, thereby improving stability of light emission of the light-emitting units 200.

In this embodiment, in order to further improve the stability of electrical connection between the light-emitting units 200 and the electrode assembly 300, the positions of the light-emitting units 200 overlapping the first branch electrodes 311 and the second branch electrodes 321 can also be reinforced by welding.

In this embodiment, referring to FIG. 7, the encapsulation glue layer 500 may only cover the light-emitting units 200. Namely, the quantum-dot glue layer 400 disposed on the encapsulation glue layer 500 and the first branch electrodes 311 and the second branch electrodes 321 of the electrode assembly 300 may be in direct contact. At present, the quantum-dot glue layer 400 can perform electroluminescence by the electrode assembly 300.

In this embodiment, referring to FIG. 8, the encapsulation glue layer 500 may also completely cover the light-emitting units 200, the first branch electrodes 311, and the second branch electrodes 321. Namely, the first branch electrodes 311 and the second branch electrodes 321 are insulated and separated from the quantum-dot glue layer 400 by the encapsulation glue layer 500. At present, the quantum-dot glue layer 400 can perform photoluminescence by the light-emitting unit 200.

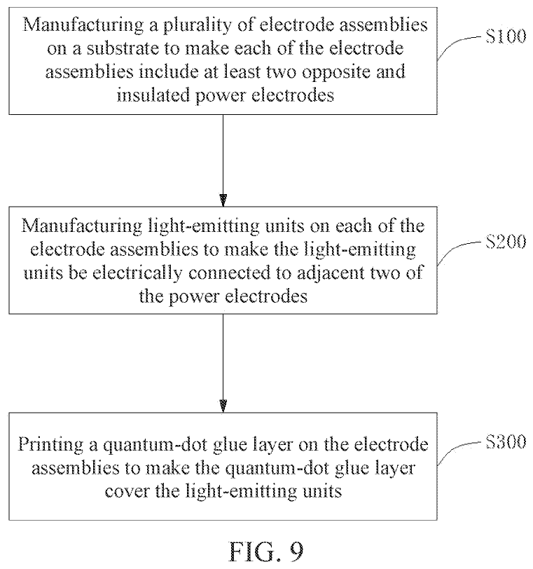

The embodiment of the present disclosure also provides a method for manufacturing a display panel. Please refer to FIG. 9, which will be described in detail below. It should be noted that the order of description in the following embodiments is not meant to limit the preferred order of the embodiments.

The present disclosure provides a method for manufacturing a display panel, including:

S100: manufacturing a plurality of electrode assemblies 300 on a substrate to make each of the electrode assemblies 300 include at least two opposite and insulated power electrodes.

S200: manufacturing light-emitting units 200 on each of the electrode assemblies 300 to make the light-emitting units 200 be electrically connected to adjacent two of the power electrodes.

In this embodiment, by the above steps, the light-emitting units 200 can be directly manufactured on the substrate with a driving circuit, so that steps of transferring a massive amount of LED chips can be omitted, to overcome disadvantages of complication and time consumption on a method for transferring a massive amount, thereby being conducive to low-cost preparation of large-size LED displays.

In this embodiment, step S200 may include:

S210: printing a solution containing a plurality of light-emitting units 200 on the electrode assembly 300.

In this embodiment, the solution containing the light-emitting units 200 may also include solvents such as propylene glycol methyl ether acetate (PGMEA), alcohols (such as ethanol), water, ethers (such as diethyl ether), esters (such as ethyl acetate), alkanes (such as n-octane), and the like.

In this embodiment, the solution containing the light-emitting units 200 may also include a ligand compound, such as one of a glycol derivative, a thiothiol compound, a thiocarboxylic acid compound, and a compound containing an ester group and a thiol group.

S220: applying a pulse signal to the electrode assemblies 300, so that first ends of the light-emitting units 200 overlap with the first branch electrodes 311, and second ends of the light-emitting units 200 overlap with the adjacent second branch electrodes 321.

In this embodiment, an arrangement of the light-emitting units 200 (Nanorod LED) can be controlled by controlling a magnitude of a voltage and a frequency of the pulse signal.

S230: welding for strengthening positions of the light-emitting unit 200 overlapping the first branch electrodes 311 and the second branch electrodes 321 to strengthen conductivity stability between the light-emitting unit 200 and the first branch electrodes 311 as well as the second branch electrode 321.

In this embodiment, the solvent in the solution for the light-emitting unit 200 can be first heated and dried, and the light-emitting units 200 are then welded and strengthened with the first branch electrodes 311 and the second branch electrodes 321.

In this embodiment, by applying the pulse signal to the electrode assemblies 300, the light-emitting units 200 can follow patterned electrodes (i.e., the first branch electrodes 311 and the second branch electrodes 321) within the electrode assemblies 300 arranged in an orderly manner under the action of an electric field. Namely, in this embodiment, by combining electro-arrangement and electrophoretic deposition, the light-emitting units 200 in each of the pixel units 100 are arranged regularly and efficiently to improve uniformity of light emission.

In the method for manufacturing the display panel of the present disclosure, the method for manufacturing the display panel may further include:

S300: printing a quantum-dot glue layer 400 on the electrode assemblies 300 to make the quantum-dot glue layer 400 cover the light-emitting units 200.

In this embodiment, the quantum-dot glue layer 400 is manufactured on the light-emitting units 200 by inkjet printing, and LED and quantum dot (QD) technologies are combined to give the display panel more excellent color performance.

In this embodiment, step S300 may include:

S310, manufacturing an encapsulation glue layer on the electrode assemblies 300.

In this embodiment, the encapsulation glue layer may completely cover the electrode assemblies 300 and the light-emitting units 200 or only cover the light-emitting units 200. A specific encapsulation method used depends on the contrast of the electroluminescence/photoluminescence performance of the quantum-dot glue layer 400 and is not specifically limited in this embodiment.

S320: manufacturing a quantum-dot glue layer 400 on the encapsulation glue layer to make the quantum-dot glue layer 400 cover the light-emitting units 200.

In this embodiment, the quantum-dot glue layer 400 may also include solvents such as propylene glycol methyl ether acetate (PGMEA), alcohols (such as ethanol), water, ethers (such as diethyl ether), esters (such as ethyl acetate), and alkanes (such as n-octane).

S330: energizing the quantum-dot glue layer 400 to volatilize a solvent in a material of the quantum-dot glue layer 400 and solidify to form a quantum-dot film.

In this embodiment, if the quantum-dot glue layer 400 is electrically connected to the electrode assemblies 300, electrical curing of the quantum-dot glue layer 400 can be achieved by energizing the electrode assemblies 300.

In this embodiment, by using the above steps to combine inkjet printing with electrophoretic deposition, which can avoid a coffee ring generated by solvent volatilization. Under the action of electrical signals, quantum dots can be gathered together, and the quantum dots show a special aggregation structure, affecting a refractive index of the quantum-dot film to make the light efficiency of the quantum-dot film higher.

An embodiment of the present disclosure also provides a mobile terminal, which includes the terminal body and the display panel, wherein the terminal body and the display panel are combined into a whole. In this embodiment, the mobile terminal may be a terminal device, such as a computer and a mobile phone.

In this embodiment, each of the electrode assemblies 300 is disposed in one of the pixel units 100, and the light-emitting units 200 electrically connected to the power electrodes are disposed between at least two opposite and insulated power electrodes of the electrode assembly 300, so that the light-emitting units 200 are arranged within the electrode assembly 300 in an orderly manner, thereby achieving effects of more uniform light emission and stronger brightness. Moreover, by the above structure, the present disclosure can save a massive transfer process of chips, thereby overcoming disadvantages of strict and time-consuming chip yield control requirements caused by the massive transfer process of chips, which is beneficial to reduce the production cost of LED large-size display equipment. In addition, In this embodiment, the quantum-dot glue layer 400 is provided on the light-emitting units 200 to combine quantum dot and LED technologies and utilize the photoluminescence properties of quantum dots and the excellent color performance of quantum dots, which gives the display panel more excellent color performance, and can significantly improve the light efficiency of the entire display panel and reduce the IR drop, to be more energy-saving, which is conducive to the manufacture of large-size-quantum-dot LED display components (QD-LED components) or display devices.

A detailed introduction to a display panel, a manufacturing method thereof, and a mobile terminal provided by the embodiments of the present disclosure is mentioned above. Specific examples are used herein to explain the principles and implementations of the present disclosure. The description of the above embodiments is only used to help understand the methods and core ideas of the present disclosure. Meanwhile, for those skilled in the art, according to the ideas of the present disclosure, there will be changes in the specific implementation and scope of applications. In summary, the content of the present disclosure should not be understood as a limitation of the present disclosure.

What is claimed is:

1. A display panel, comprising a plurality of pixel units, wherein each of the pixel units comprises:
a plurality of light-emitting units, wherein adjacent two of the light-emitting units are separately arranged; and
an electrode assembly comprising at least two opposite and insulated power electrodes, wherein each of the light-emitting units is electrically connected to adjacent two of the power electrodes.

2. The display panel as claimed in claim 1, wherein the electrode assembly comprises:
a first power electrode comprising a plurality of first branch electrodes, wherein adjacent two of the first branch electrodes are arranged in parallel.

3. The display panel as claimed in claim 2, wherein the electrode assembly further comprises a second power electrode, the second power electrode comprises a plurality of second branch electrodes, and adjacent two of the second branch electrodes are arranged in parallel.

4. The display panel as claimed in claim 3, wherein the first branch electrodes and the second branch electrodes are arranged in parallel and alternatively.

5. The display panel as claimed in claim 4, wherein each of the light-emitting units is electrically connected to two adjacent first and second branch electrodes.

6. The display panel as claimed in claim 5, wherein the first power electrode further comprises a first side-branch electrode electrically connected to the first branch electrodes.

7. The display panel as claimed in claim 6, wherein the second power electrode further comprises a second side-branch electrode electrically connected to the second branch electrodes.

8. The display panel as claimed in claim 7, wherein the first side-branch electrode and the second side-branch electrode are arranged in parallel.

9. The display panel as claimed in claim 8, wherein a direction that the first side-branch electrode and the second side-branch electrode extend is perpendicular to a direction that the first branch electrodes and the second branch electrodes are arranged.

10. The display panel as claimed in claim 7, wherein the first branch electrodes and the second branch electrodes are located between the first side-branch electrode and the second side-branch electrode.

11. The display panel as claimed in claim 10, wherein each of the first branch electrodes and the second branch electrodes is a linear electrode formed in a straight-line shape, a broken-line shape, or a curved shape.

12. The display panel as claimed in claim 5, wherein in a direction that the first branch electrodes and the second branch electrodes are arranged, a length of each of the light-emitting units is greater than or equal to a distance between the first and second branch electrodes.

13. The display panel as claimed in claim 12, wherein in the direction that the first branch electrodes and the second branch electrodes are arranged, the length of each of the light-emitting units is smaller than twice the distance between the first and second branch electrodes.

14. The display panel as claimed in claim 1, wherein the display panel further comprises a quantum-dot glue layer disposed on the electrode assembly.

15. The display panel as claimed in claim 14, wherein the quantum-dot glue layer covers the light-emitting units.

16. The display panel as claimed in claim 15, wherein the display panel further comprises an encapsulation glue layer disposed between the electrode assembly and the quantum-dot glue layer.

17. The display panel as claimed in claim 16, wherein the encapsulation glue layer covers the light-emitting units.

18. The display panel as claimed in claim 1, wherein a material of each of the light-emitting units comprises a semiconductor compound composed of at least two elements of boron group elements, carbon group elements, and nitrogen group elements.

19. A method for manufacturing a display panel, comprising:
manufacturing a plurality of electrode assemblies on a substrate to make each of the electrode assemblies comprise at least two opposite and insulated power electrodes; and
manufacturing light-emitting units on each of the electrode assemblies to make the light-emitting units be electrically connected to adjacent two of the power electrodes.

20. A mobile terminal, comprising a terminal body and the display panel as claimed in claim 1, wherein the terminal body and the display panel are combined into a whole.
